(19) United States
(12) Patent Application Publication
(10) Pub. No.: US 2005/0145177 A1
(43) Pub. Date: Jul. 7, 2005

(54) Method and apparatus for low temperature silicon nitride deposition

(76) Inventors: Michael McSwiney, Hillsboro, OR (US); Timothy McWilliams, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/750,062

(22) Filed: Dec. 30, 2003

(51) Int. Cl. C23C 16/00; B05D 3/00

(52) U.S. Cl. 118/723 MA; 427/248.1; 427/561

(57) ABSTRACT

Numerous embodiments of a method and apparatus for low temperature silicon nitride deposition are disclosed. In one embodiment, a halogen substituted silicon hydride and a nitrogen-containing precursor are added to a chamber. An operating temperature of the chamber is set below 550 ° C. and a silicon nitride layer is deposited on a substrate.

### TECHNICAL FIELD

Embodiments of this invention relate to the field of semiconductor processing and the fabrication of integrated circuits. In particular, embodiments of the present invention provide a method and apparatus for low temperature silicon nitride deposition.

### BACKGROUND

Silicon nitride (having the general chemical formula Si₃N₄) has suitable passivation properties which make it ideal for use in the semiconductor industry as an insulator and protective layer for silicon devices (e.g., transistors, circuit devices). Also, by changing the deposition conditions, silicon nitride can be made into excellent storage layer in silicon magnetic storage devices.

A silicon nitride layer can be deposited on a wafer placed in a deposition chamber from the reaction of a silicon source (e.g., silane (SiH₄)) with a nitrogen source (e.g., ammonia (NH₃) or nitrogen (N₂)). A relatively high operating temperature, typically at temperatures above 550° C., is required to drive the reaction of the silicon source and nitrogen source to form silicon nitride. This high temperature threshold creates several problems. Temperature sensitive critical layers (e.g., tips, wells, halos) used in transistor fabrication may be damaged by the reaction temperature. Also, thermal budgets for high-volume transistor production may be increased, while decreasing the efficiency of transistor production due to damaged temperature sensitive critical layers.

### BRIEF DESCRIPTION OF THE DRAWINGS

Embodiments of the present invention are illustrated by way of example, and not limitation, in the figures of the accompanying drawings in which:

FIG. 1 illustrates a schematic of a system that may be used for silicon nitride deposition.

FIG. 2A-2D illustrate chemical reactions for low temperature silicon nitride deposition.

FIG. 3 illustrates the Lewis structure of dibromosilane.

FIG. 4 illustrates the Lewis structures of tetrabromosilane and dichlorodifluorosilane.

FIG. 5 illustrates the Lewis structures of tricholorovinyl-silane, chloromethyl(trichloro)-silane, dichloromethylvinyl-silane, and chlorodimethyl-silane.

FIG. 6 illustrates the Lewis structures of monochlorodisilane, 1,1-dichlorodisilane, and 1,1,2,2-tetrachlorodisilane.

FIG. 7 illustrates the Lewis structures of hexabromodisilane and hexaiododisilane.

FIG. 8 illustrates the Lewis structures of 1,1,2,2-tetrachloro-1,2-dimethyldisilane, 1,2-dichlorotetramethyldisilane, and chloropentamethyldisilane.

FIG. 9 illustrates the Lewis structures of precursor solvents hexane, octane, and nonane.

FIG. 10 illustrates the Lewis structures of hydrazine and dimethyl hydrazine.

FIG. 11 illustrates the Lewis structure of 1-tertiarybultylamino-2,4 -ditertiarybutylcyclodisilazane, 1,1,3,3,5,5,7,7-octamethylcyclotetrasilazane, and 1-tertiarybutylaminosilylcyclopropane.

FIG. 12 illustrates one embodiment of a deposition system.

FIG. 13 illustrates one embodiment of a silicon nitride deposition system.

FIG. 14 illustrates an alternative embodiment of a silicon nitride deposition system.

FIG. 15 illustrates an alternative embodiment of a silicon nitride deposition system.

FIG. 16 illustrates an alternative embodiment of a silicon nitride deposition system.

FIG. 17 illustrates the Lewis structures of substituted/unsubstituted silyl cyclopropane and substituted/unsubstituted cyclobutane.

FIG. 18 is a flow chart illustrating one embodiment of low temperature silicon nitride deposition.

FIG. 19 is a flow chart illustrating an alternative embodiment of low temperature silicon nitride deposition.

FIG. 20 is a flow chart illustrating an alternative embodiment of low temperature silicon nitride deposition.

### DETAILED DESCRIPTION

In the following description, numerous specific details are set forth such as examples of specific materials or components in order to provide a thorough understanding of embodiments of the present invention. It will be apparent, however, to one skilled in the art that these specific details need not be employed to practice embodiments of the present invention. In other instances, well known components or methods have not been described in detail in order to avoid unnecessarily obscuring embodiments of the present invention.

The terms “on,” “above,” “below,” “between,” and “adjacent” as used herein refer to a relative position of one layer or element with respect to other layers or elements. As such, a first element disposed on, above or below another element may be directly in contact with the first element or may have one or more intervening elements. Moreover, one element disposed next to or adjacent another element may be directly in contact with the first element or may have one or more intervening elements.

Any reference in the specification to “one embodiment” or “an embodiment” means that a particular feature, structure, or characteristic described in connection with the embodiment is included in at least one embodiment of the claimed subject matter. The appearances of the phrase, “in one embodiment” in various places in the specification are not necessarily all referring to the same embodiment.

Embodiments of a method and apparatus for low temperature silicon nitride deposition are described, thereby preventing damage to temperature sensitive critical layers (e.g., tips, wells, and halos) and reduction in thermal production costs. In one embodiment of the present invention, silicon nitride precursors such as partially or fully halogen-substituted silanes/disilanes may be reacted with a nitrogen source to form a silicon nitride layer for deposition on a substrate (e.g., a wafer) at temperatures below 550° C. In an alternative embodiment of the present invention, one or more silicon-containing precursors may be exposed to an energy source (e.g., ultraviolet (UV)) to activate a precursor to enhance its reactivity to facilitate low temperature silicon nitride deposition. In another embodiment of the present invention, a precursor solution, in which one or more silicon containing or nitrogen containing precursors are mixed in a suitable solvent, may be used to facilitate low temperature silicon nitride deposition.

Embodiments of the present invention herein for low temperature silicon nitride deposition is generally described with respect to deposition of a silicon nitride layer in a diffusion furnace. However, it may be appreciated by one of skill in the art that other deposition techniques may be used, including but not limited to, a vertical diffusion furnace (VDF), horizontal diffusion furnace (HDF), chemical vapor deposition (CVD), plasma enhanced chemical vapor deposition (PECVD), atomic layer deposition (ALD), and radical assisted ALD.

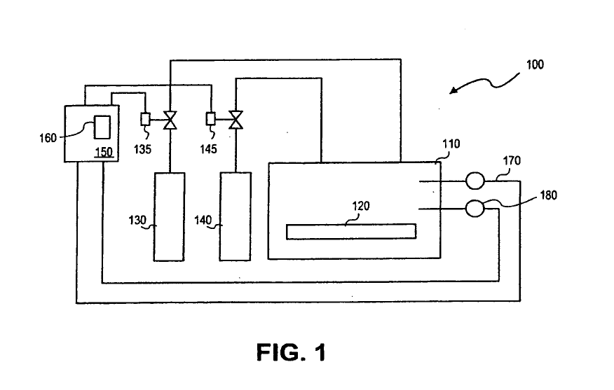

FIG. 1 illustrates a schematic of a system 100 that may be used for forming a silicon nitride layer or film on a substrate. System 100 includes chamber 110 that is, for example, a VDF, CVD, PECVD, or an ALD chamber. Situated in chamber 110 is one or more substrates 120 located in chamber 110 for silicon nitride deposition. Substrate 120 may be any surface, generated when making an integrated circuit, upon which a conductive layer may be formed. Substrate 120 thus may include, for example, active and passive devices that are formed on a silicon wafer such as transistors, capacitors, resistors, diffused junctions, gate electrodes, local interconnects, etc. . . . Substrate 120 also may include insulating materials that separate such active and passive devices from the conductive layer or layers that are formed on top of them, and may include previously formed conductive layers.

Silicon nitride films/layers are amorphous insulating materials that may be applicable in various areas of large scale integration fabrication. For example, silicon nitride may be final passivation and mechanical protective layers for integrated circuits, masks for selective oxidation of silicon, dielectric materials in the stacked oxide-nitride-oxide layers in dynamic random access memory (DRAM) capacitors, and sidewall spacers in metal-oxide semiconductor field-effect transistors (MOSFETs). Silicon nitride may also be etch-stop layers in damascene structures.

Connected to chamber 110 are silicon source precursor 130 and nitrogen source precursor 140. Additional precursor sources may be connected to chamber 110 as well, such as precursor sources for additional species or inerts. Transportation of the precursor (which may be a solid, liquid, or gas) to the deposition chamber may be accomplished through numerous methods including, but not limited to, bubbling, vapor draw, and direct liquid injection. The entry of, in this instance, a silicon source precursor or a nitrogen source precursor is controlled by valve 135 and valve 145, respectively, that are each connected to controller 150. Controller 150 includes memory 160 that has therein instructions for introduction of silicon source precursor 130 and nitrogen source precursor 140. Those instructions include, in one embodiment, the introduction to form a silicon nitride layer. Also connected to chamber 110 and controlled by controller 150 is a heat source (i.e., a thermal energy source) to elevate an operating temperature of the chamber. FIG. 1 further shows temperature sensor 170 that is connected to controller 150 and may be used by controller 150 to control a temperature inside chamber 110. In embodiments described herein, a silicon nitride layer formation process may be conducted at a temperature of 550° C. or less. Thus, instructions, for example, in memory 160 may maintain the temperature in chamber 110 at 550° C. or less for a silicon nitride layer formation process. Finally, system 100 may also include a pressure sensor 180 connected to controller 150 to monitor pressure inside chamber 110. In one example, chamber 110 may be connected to a vacuum or other pressure regulator.

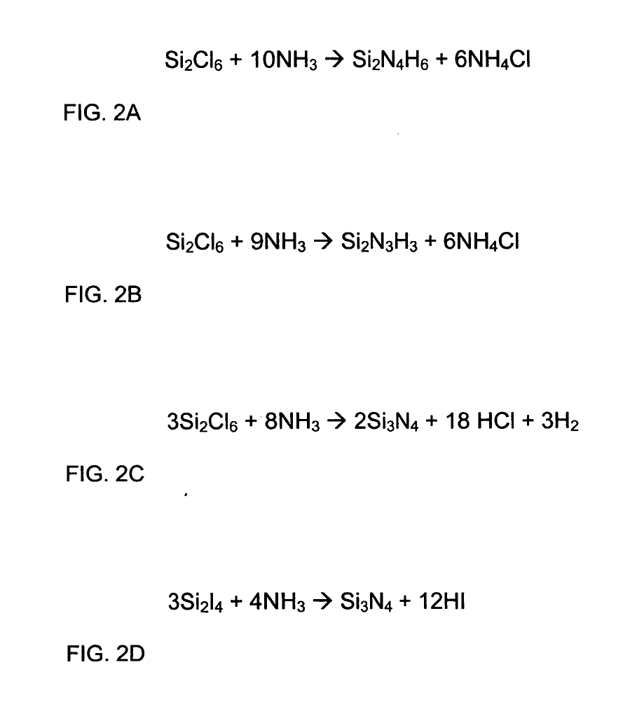

In one embodiment of the present invention, partially or fully halogen-substituted silanes or disilanes (i.e., silicon precursor sources) are reacted with a nitrogen source to form a silicon nitride deposition layer on a substrate at reduced temperatures, in particular, below 550° C. Silanes are generally saturated silicon hydrides with the general formula of SinH₂ₙ₊₂. FIGS. 2A-2D illustrate reactions that may be achieved at temperatures below 550° C. between halogen substituted silanes and a nitrogen source to produce silicon nitride, in several embodiments of the present invention. FIGS. 2A and 2B illustrate the reaction of hexachlorodisilane (“HCD”) with ammonia to produce silicone nitride. In one embodiment of the present invention, the reactions may occur near room temperature (e.g., 21-23° C.). FIG. 2C illustrates another example of a reaction between HCD and ammonia to produce silicon nitride. In one embodiment of the present invention, the reaction illustrated in FIG. 2C may be achieved at a temperature higher than room temperature but below 550° C. FIG. 2D illustrates the reaction of silicon iodide with ammonia to produce silicon nitride in yet another example of forming silicon nitride at temperatures below 550° C.

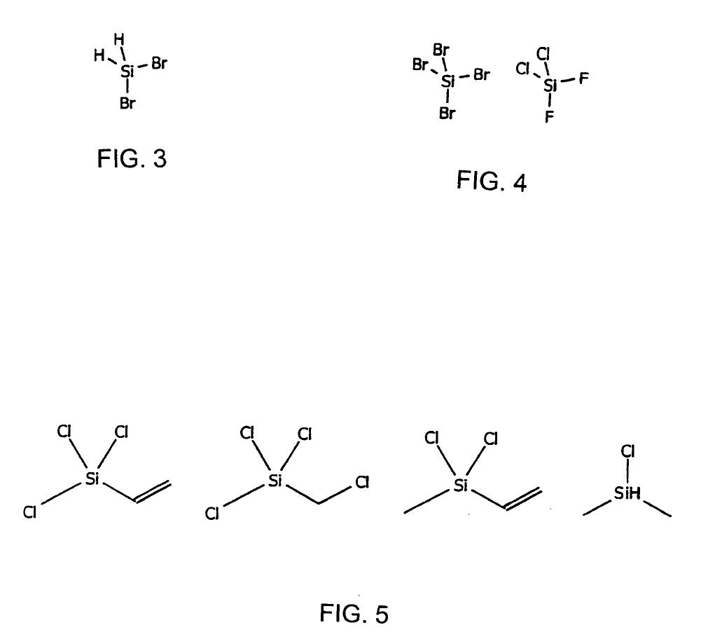

In order to reduce the temperature for silicon nitride deposition, the silicon and the nitrogen precursor sources should be highly reactive. In one embodiment of the present invention, partially and fully halogen-substituted silanes and disilanes may be the silicon precursor source. Halogens increase the reactivity of silanes through the introduction of polar bonds. Polar bonds create local areas of differing charge density which permit nucleophilic or electrophilic attack by other reactive species. A partially halogen-substituted silane may have the general formula:
SiHₐX₄₋ₐ
where 3≧a≧1; X=Fluorine (F), Chlorine (Cl), Bromine (Br), or Iodine (I). This class of compounds includes, but is not limited to, dibromosilane, tribromosilane, iodosilane, di-iodosilane, and tri-iodosilane. FIG. 3 illustrates the Lewis structure of dibromosilane, an example of a partially halogen-substituted silane that may be used as a silicon precursor source for low temperature silicon nitride deposition (e.g., below 550° C.).

In another embodiment of the present invention, the silicon source may be a fully halogen-substituted silane having the general formula:
SiX₄
where X=F, Cl, Br, or 1. This class of compounds includes, but is not limited to, tetrabromosilane, tetraiodosilane, and dichlorodifluorosilane. FIG. 4 illustrates the Lewis structures of tetrabromosilane and dichlorodifluorosilane, examples of fully halogen-substituted silanes that may be used as a silicon precursor source for low temperature silicon nitride deposition (e.g., below 550° C.).

In another embodiment of the present invention, the silicon source may be an alky-halogenated silane having the general formula:
SiHₐX_{b}R_{c}
where 3≧a≧0; 3 b≧0; 3≧c≧0; a+b+c=4;
X=F, Cl, Br, 1, or a mixture of different halogens (e.g., SiCl₂F₂); and
R is an alky group that includes, but is not limited to, ethyl, chloroethyl, propyl, t-butyl, and isopropyl. If more than one “R” group is present, the “R” groups may be of different groups (e.g., dichloromethylvinyl-silane).

Classes of alky-halogenated silane compounds include, but are not limited to tricholorovinyl-silane, trichloromethyl-silane, chloromethyl(trichloro)-silane, dichloromethylvinyl-silane, and methyldichloro-silane. FIG. 5 illustrates the Lewis structures of tricholorovinyl-silane, chloromethyl(trichloro)-silane, dichloromethylvinyl-silane, and chlorodimethyl-silane, examples of alky-halogenated silanes that may be used as a silicon precursor source for low temperature silicon nitride deposition (e.g., below 550° C.).

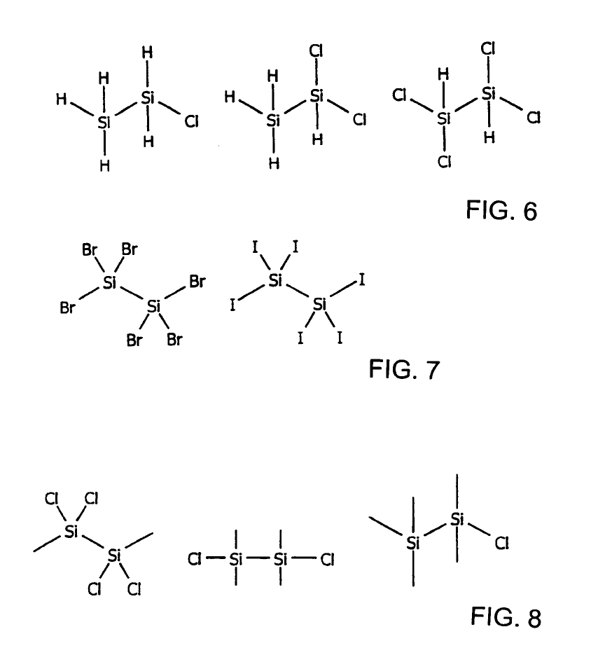

In another embodiment of the present invention, the silicon source may be a partially halogen-substituted disilane having the general formula:
Si₂HₐX₆₋ₐ
where 5≧a≧1; and X=F, Cl, Br, I, or a mixture of halogens. With Cl as a representative halogen, this category includes, but is not limited to, monochlorodisilane, 1,1-dichlorodisilane, 1,2-dichlorodisilane, 1,1,1-trichlorodisilane, 1,1,2-trichlorodisilane, 1,1,1,2-tetrachlorodisilane, 1,1,2,2-tetrachlorodisilane, and pentachlorosilane. FIG. 6 illustrates the Lewis structures of monochlorodisilane, 1,1-dichlorodisilane, and 1,1,2,2-tetrachlorodisilane, examples of partially halogen-substituted disilanes that may be used as a silicon precursor source for low temperature silicon nitride deposition (e.g., below 550° C.).

In another embodiment of the present invention, the silicon source may be a fully halogen-substituted disilane having the general formula:
Si₂X₆
where X=F, Cl, Br, I. This class of compounds includes, but is not limited to, hexabromodisilane and hexaiododisilane. FIG. 7 illustrates the Lewis structures of hexabromodisilane and hexaiododisilane, examples of fully halogen-substituted disilanes that may be used as a silicon precursor source for low temperature silicon nitride deposition (e.g., below 550° C.).

In another embodiment of the present invention, the silicon source may be an alkyl-halogen substituted disilane having the general formula:
Si₂HₐX_{b}R_{c}
where 5≧a≧0; 5≧b≧0; 5≧c≧0; a+b+c=6;
X=F, Cl, Br, I, or a mixture of different halogens; and
R is an alky group that includes, but is not limited to, ethyl, chloroethyl, propyl, t-butyl, and isopropyl. If more than one “R” group is present, the “R” groups may be of different groups. This class of compounds includes, but is not limited to, 1,1,2,2-tetrachloro-1,2-dimethyldisilane, 1,2-dichlorotetramethyldisilane, and chloropentamethyldisilane. FIG. 8 illustrates the Lewis structures of 1,1,2,2-tetrachloro-1,2-dimethyldisilane, 1,2-dichlorotetramethyldisilane, and chloropentamethyldisilane, examples of methyl-halogen substituted disilanes that may be used as a silicon precursor source for low temperature silicon nitride deposition (e.g., below 550° C.).

For the classes of silicon precursors discussed above, the corresponding nitrogen precursor source may be, in one embodiment of the present invention, ammonia. In alternative embodiments, other nitrogen containing compounds may be used including, but not limited to, dimethylamine, diethylamine, methyl amine, ethyl amine, methylethyl amine, substituted hydrazine, or an unsubstituted hydrazine (diazane, having the general formula H₂NNH₂).

In an alternative embodiment of the present invention, a silicon-containing precursor source and the active nitrogen source may be mixed in a solvent and introduced using a single injection system (e.g., direct liquid injection into a deposition chamber). Because both precursors are dissolved in the same solvent, they are in close molecular proximity. This close proximity facilitates reactions in the deposition chamber, and can lead to the formation of transition states while still dissolved in the solvent, thereby enhancing reactivity to produce silicon nitride.

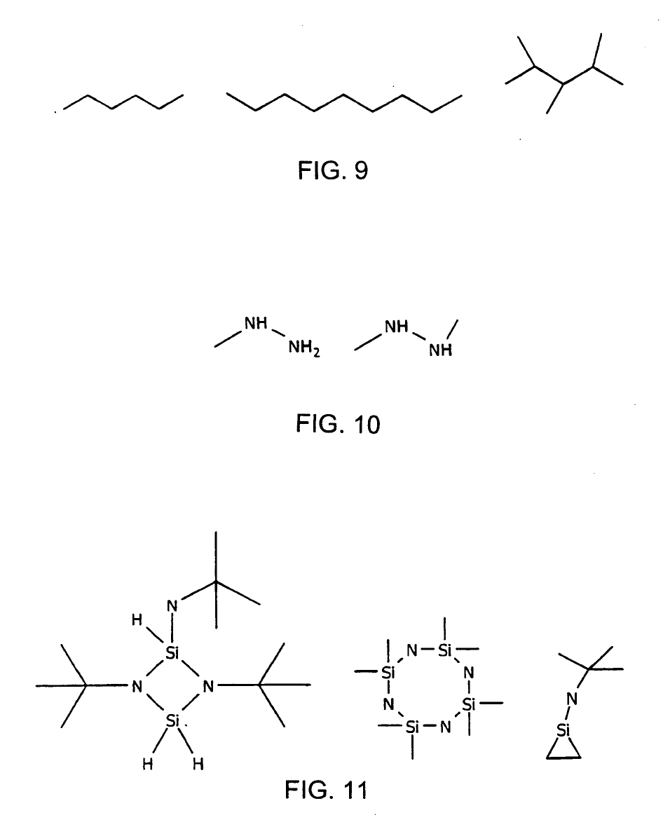

In one embodiment of the present invention, the solvent for dissolving the silicon nitride precursors may be an organic solvent, including but not limited to, hexanes, octanes, and nonanes, whose Lewis structures are illustrated in FIG. 9. The active nitrogen precursor source may be a substituted or unsubstituted hydrazine, including but not limited to dimethyl hydrazine, methyl hydrazine, and asymmetrical dimethyl hydrazine. The Lewis structures of methyl hydrazine and dimethyl hydrazine are illustrated in FIG. 10. The silicon precursor source may include, but is not limited to, linear and branched silazanes, partially and fully substituted aminosilanes with diamene ligands, silyl cyclopropane, silyl cyclobutane, and halogenated aminosilanes. The Lewis structures of 1-tertiarybultylamino-2,4-ditertiarybutylcyclodisilazane, 1,1,3,3,5,5,7,7-octamethylcyclotetrasilazane, and 1-tertiarybutylaminosilylcyclopropane are illustrated in FIG. 11.

One advantage of mixing/dissolving silicon and nitrogen precursors in a solvent is that the mixture facilitates the use of low-vapor pressure silicon precursors with attractive reactivity that normally would not be practical as an independent precursor source. In one embodiment of the present invention, the molar concentration of the silicon precursor source may be about ≦0.5 molar (M) and the molar concentration of the nitrogen precursor source may be about ≦1.0 molar (M).

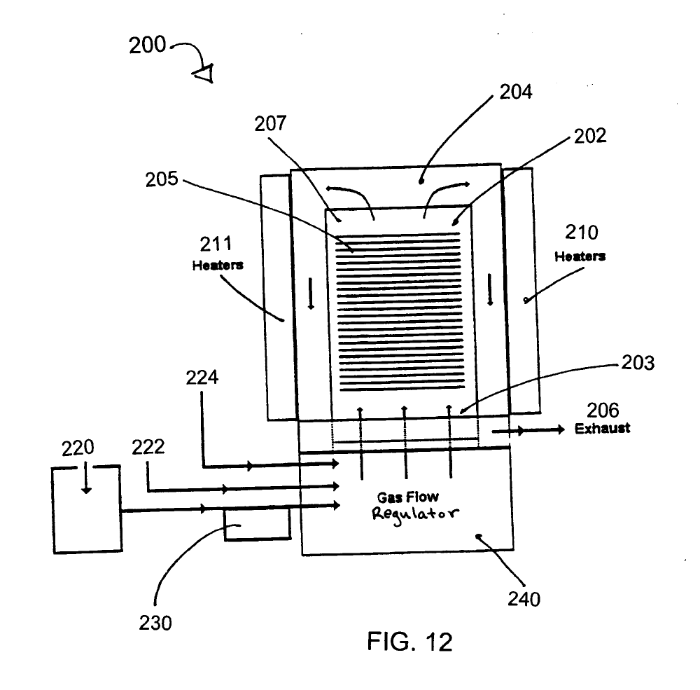

FIG. 12 illustrates a deposition scheme in one embodiment of the present invention. System 200 includes a deposition chamber 202 having one or more substrates 205 (e.g., wafers) disposed on top of each other for silicon nitride deposition. Chamber 202 includes an inlet 203 that is coupled to a gas flow regulator 240 and an outlet 207 that leads to a channel 204 for the release of gas through exhaust 206. One or more heaters or heat sources 210, 211 (i.e., thermal energy sources) may be disposed around chamber 202 and channel 204 to elevate the operating temperature of chamber 202. A mixture 220 containing silicon nitride precursors, dissolved in a solvent, is coupled to gas flow regulator 240. Mixture 220 may be disposed in a separate chamber coupled to chamber 202. In one embodiment, a direct liquid injection system 230 may be situated between mixture 220 and gas flow regulator 240 to deliver the silicon nitride precursor mix into chamber 202. In alternative embodiments, transportation of mixture 220 into chamber 202 may be accomplished through other methods including, but not limited to, bubbling and vapor draw.

As such, mixture 220 may contain a silicon precursor (e.g., silazane) and a nitrogen precursor (e.g., methyl hydrazine) dissolved in an organic solvent (e.g., hexane). Because the silicon and nitrogen precursors may have variable vapor pressures, direct liquid injection 230 may be used to inject the mixture into chamber 202 through gas flow regulator 240. Additional precursor sources 222, 224 may be coupled to gas flow regulator 240 leading to chamber 202. Heaters 210, 211 may be controlled with a temperature regulator (not shown) to an operating temperature that does not exceed 550° C. Once injected into chamber 202, the silicon nitride precursors react to form silicon nitride for layering on substrates 205. As discussed above, the solvent of mixture 220 facilitates the use of low-vapor pressure silicon precursors with attractive reactivity that normally would not be practical as an independent precursor source. Moreover, the close proximity facilitates reactions in chamber 202, and leads to the formation of transition states while still dissolved in the solvent, thereby enhancing reactivity to produce silicon nitride for deposition on substrates 205.

The deposition system described with respect to FIG. 12 may be carried out in a number of different deposition schemes, including but not limited to, CVD, PECVD, and ALD. Moreover, the deposition chamber may be a vertical diffusion furnace or a horizontal diffusion furnace. For all these schemes, the operating temperature for silicon nitride deposition is less than 550° C. This reduced temperature provides the advantage of preventing damage to temperature sensitive layers that may be involved in processing a substrate (e.g., tips, wells, halos, during transistor fabrication).

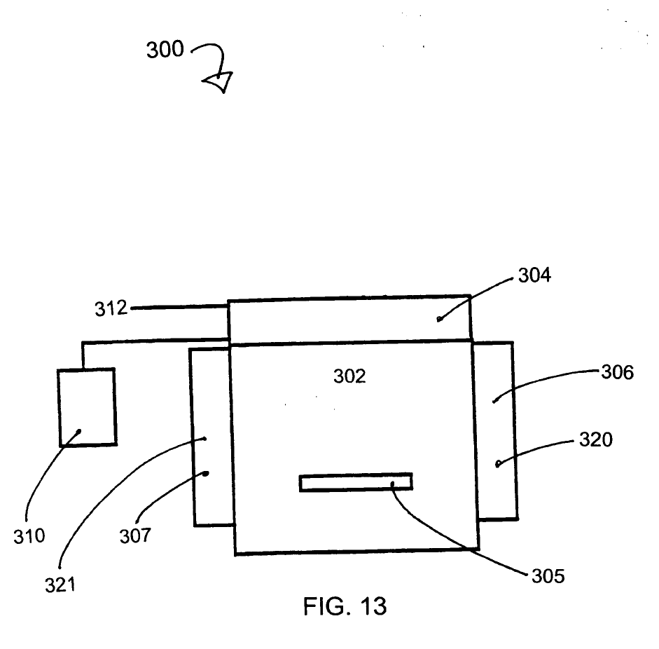

In an alternative embodiment of the present invention, silicon and nitrogen source precursors may be exposed to a certain energy source to enhance their reactivity through the creation of excited states and through photodecomposition of the silicon precursor. FIG. 13 illustrates one embodiment of a silicon nitride deposition system 300 that also includes an energy source for flood exposure of a substrate (e.g., a wafer). A chamber 302 is configured to receive one or more substrates 305. A precursor distributor 304 (e.g., a showerhead, gas inlet) is disposed above chamber 302, and one or more heat sources 306, 307 are disposed around chamber 302. In one embodiment, heat sources 306, 307 (i.e., thermal energy sources) may be heating coils disposed around chamber 302. Heat sources for deposition chambers are well known in the art; accordingly, a detailed description is not provided herein. A precursor source 310 is coupled to distributor 304, and a secondary gas source 312 may also be coupled to distributor 304. In one embodiment, precursor source 310 may be a separate chamber coupled to chamber 302. In deposition system 300, an energy source in the form of UV light 320, 321 (e.g., electromagnetic waves with a wavelength of about 10 to 700 nanometers) may be integrated within heat sources 306, 307. A UV transparent quartz liner (not shown) may be disposed around UV light 320, 321 for protection from heat sources 306, 307.

In one method for silicon nitride deposition of substrate 305, silicon nitride precursors from source 310 are passed through distributor 304 before reacting in chamber 302 under an operating temperature controlled by heat sources 306, 307. The precursors may also be exposed/flooded with UV light from UV sources 320, 321 to enhance the reactivity of the silicon and nitrogen precursors to facilitate low temperature silicon nitride deposition, through the formation of excited states or through photo-decomposition of a precursor. In one method, the precursors may be exposed to UV light prior to raising the operating temperature of chamber 302. Alternatively, the precursors may be exposed to UV light while chamber 302 is set to an operating temperature. In any case, the operating temperature of chamber 302 is less than 550° C.

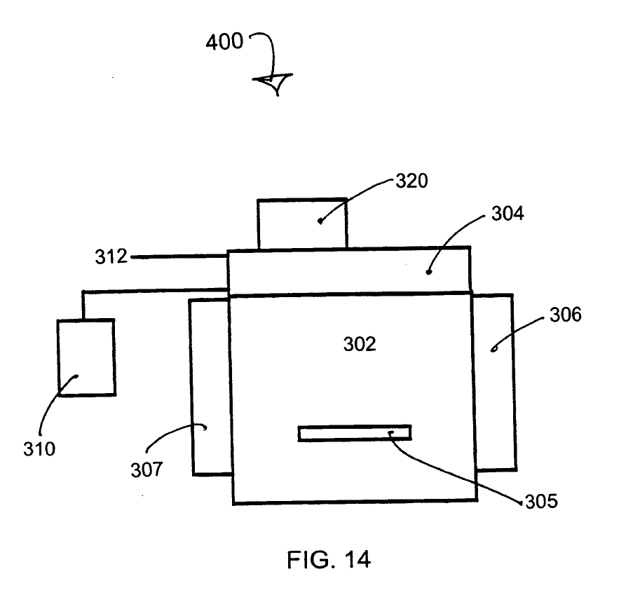

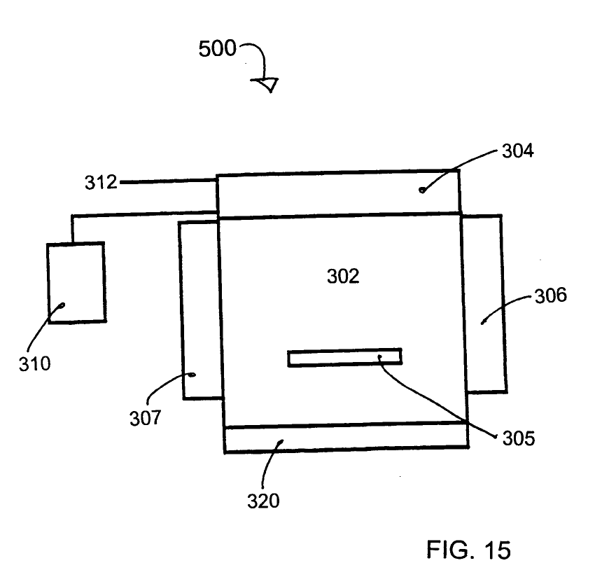

FIGS. 14 and 15 illustrate embodiments of silicon nitride deposition systems with alternative placements for UV light source 320. In deposition system 400 of FIG. 14, UV light source 320 is disposed near distributor 304 (e.g., a showerhead or gas inlet). As such, the silicon and nitrogen precursors from precursor source 310 are exposed to UV light when initially passed through distributor 304 and before entering chamber 302. Moreover, this location may create excited states or induce photochemical reactions away from the substrate surface. This can afford better uniformity of reactants across the deposition chamber. Distributor 304 may also be adapted to receive a gas from secondary gas source 312. However, the precursors may still be exposed to the UV light within chamber 302 while reacting to form silicon nitride at an operating temperature below 550° C. (as controlled by heat sources 306, 307).

In deposition system 500 of FIG. 15 illustrates UV light source 320 disposed near a bottom side of chamber 302 (i.e., near an opposite side of distributor 304). In this configuration, the silicon nitride precursors from precursor source 310 are exposed to UV light after entering chamber 302. UV light may be projected or reflected into chamber 302 allowing the photodecomposition and any photo-reaction to take place near a substrate surface. As discussed above, UV light enhances the reactivity of the silicon and nitrogen precursors to facilitate low temperature silicon nitride deposition through the formation of excited states or through photo-decomposition of a precursor. In one method, the precursors may be exposed to UV light prior to raising the operating temperature of chamber 302. Alternatively, the precursors may be exposed to UV light while chamber 302 is set to an operating temperature. In any case, the operating temperature of chamber 302 is less than 550° C.

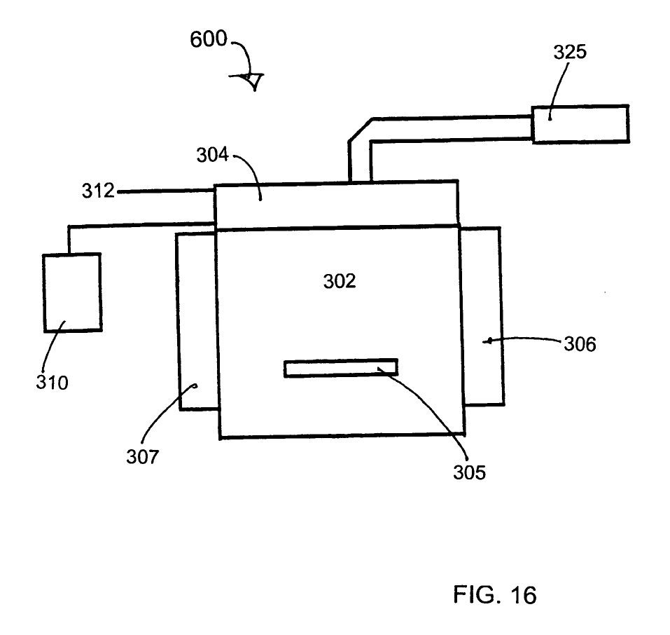

FIG. 16 illustrates yet another embodiment of a silicon nitride deposition system 600 in which a microwave energy source 325 is coupled to chamber 302 (as an alternative to a UV light energy source). Microwave energy (e.g., electromagnetic radiation with a wavelength of about 30 centimeters to about 1 millimeter) may create excited states or induce reactions between the silicon nitride precursors in a manner similar to UV energy. Microwave energy source 325 is disposed near distributor 304, to expose the silicon nitride precursors near a top side of chamber 302. As such, microwave energy source 325 may be configured to flood the silicon nitride precursors from precursor source 310 and secondary gas source 312 when passed through distributor 304. Exposing the silicon nitride precursors to microwave energy allows for silicon nitride deposition of substrate 305 at operating temperatures below 550° C.

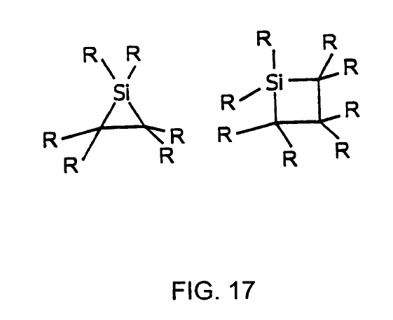

In one embodiment of the present invention, the silicon containing precursor may be sensitive to UV light, or to electromagnetic radiation at other wavelengths. FIG. 17 illustrates the Lewis structures of two chemical families of silicon containing precursors that may be UV sensitive: substituted/unsubstituted silyl cyclopropane and its derivative compounds (including but not limited to amine substitutions, halogen substitutions, and alkyl substitutions) and substituted/unsubstituted cyclobutane and its derivative compounds (including but not limited to amine substitutions, halogen substitutions, and alkyl substitutions).

The deposition systems described above with respect to FIGS. 13-16 may be carried out in a number of different deposition schemes, including but not limited to, CVD, PECVD, and ALD. Moreover, the deposition chamber may be a vertical diffusion furnace or a horizontal diffusion furnace. For all these schemes, the operating temperature for silicon nitride deposition is less than 550° C. This reduced temperature provides the advantage of preventing damage to temperature sensitive layers that may be involved in processing a substrate (e.g., tips, wells, halos, during transistor fabrication).

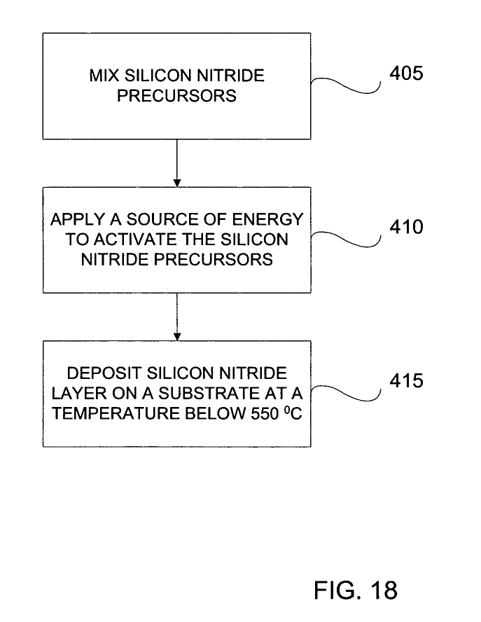

FIGS. 18-20 illustrate alternative methods for low temperature silicon nitride deposition (e.g., below 550° C.). Highly reactive silicon and nitrogen precursors are mixed to form the silicon nitride layer, block 405. In one embodiment, the silicon precursor source may be a partially or fully halogen-substituted silane, for example, dibromosilane and dichlorodifluorosilane. Alternatively, the silicon precursor may be a partially or fully halogen-substituted disilane, for example, 1,1-dichlorodisilane and hexaiododisilane. The silicon nitride precursors may then be exposed to an energy source, such as UV light, block 410. Alternatively, the energy source may be microwave energy. Upon exposure to the energy source, the silicon nitride precursors react to form a silicon nitride layer on a substrate at an operating temperature below 550° C., block 415. In one embodiment, the operating temperature may be room temperature. The deposition of the substrate may be carried out in a VDF or through CVD, PECVD, ALD, or radical assisted ALD.

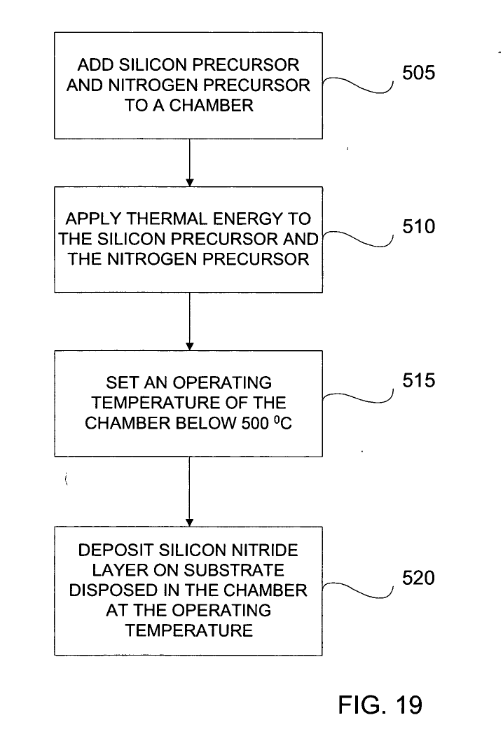

FIG. 19 illustrates yet another alternative embodiment for low temperature silicon nitride deposition. A silicon precursor and a nitrogen precursor are added to a deposition chamber, block 505. In one embodiment, the precursors may be mixed with an organic solvent in a second chamber coupled to the deposition chamber. For example, a silicon precursor (e.g., silazane) and a nitrogen precursor (e.g., methyl hydrazine) may be dissolved in an organic solvent (e.g., hexane). One advantage of mixing/dissolving silicon and nitrogen precursors in a solvent is that the mixture facilitates the use of low-vapor pressure silicon precursors with attractive reactivity. The mixture may be done outside of a deposition chamber (e.g., chamber 302). The silicon nitride precursor mixture may be injected into a deposition chamber (e.g., chamber 302) with a gas carrier. Thermal energy is applied to the silicon nitride precursors in the deposition chamber, block 510. An operating temperature of the chamber is set below 550° C., block 515. A silicon nitride layer is deposited on a substrate at an operating temperature, block 520.

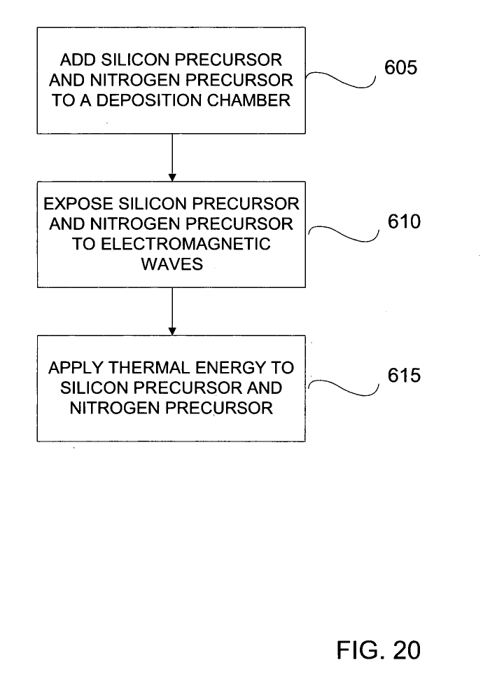

FIG. 20 illustrates an alternative embodiment for low temperature silicon nitride deposition. A silicon precursor and a nitrogen-containing precursor are added to a deposition chamber, block 605. In one embodiment, silicon containing precursors may be substituted/unsubstituted silyl cyclopropane and substituted/unsubstituted cyclobutane. The silicon nitride precursors are exposed to electromagnetic waves, block 610. In one embodiment, the electromagnetic waves have a wavelength of about 10 nanometers to about 1 millimeter. In an alternative embodiment, the electromagnetic waves may be UV light to enhance the reactivity of the silicon and nitrogen precursors to facilitate low temperature silicon nitride deposition through the formation of excited states or through photo-decomposition of a precursor. Thermal energy is applied to the silicon and nitrogen precursors, block 615. In one embodiment, the reaction between the silicon and nitrogen precursors form a silicon nitride layer on a substrate at an operating temperature below 550° C.

In the foregoing specification, the invention has been described with reference to specific exemplary embodiments thereof. It will, however, be evident that various modifications and changes may be made thereto without departing from the broader spirit and scope of embodiments of the invention as set forth in the appended claims. The specification and figures are, accordingly, to be regarded in an illustrative rather than a restrictive sense.

1. A method, comprising:
adding a halogen substituted silicon hydride and a nitrogen-containing precursor to a first chamber;
applying a thermal energy to the halogen substituted silicon hydride and the nitrogen-containing precursor;
setting an operating temperature of the first chamber below 550° C., and
depositing a silicon nitride layer on a substrate disposed in the first chamber at the operating temperature.

2. The method of claim 1, wherein adding further comprises pre-mixing the halogen substituted silicon hydride and the nitrogen-containing precursor in a second chamber coupled to the first chamber.

3. The method of claim 2, wherein the halogen substituted silicon hydride has the general formula:
SiHₐX₄₋ₐ
where a is an integer less than or equal to three and greater than or equal to one, and
X is a halogen.

4. The method of claim 2, wherein the halogen substituted silicon hydride has the general formula;
SiX₄
where X is a halogen.

5. The method of claim 2, wherein the halogen substituted silicon hydride has the general formula:
SiHₐX_{b}R_{c}
where a is an integer less than or equal to three and greater than or equal to zero,
where b is an integer less than or equal to three and greater than or equal to zero,
where c is an integer less than or equal to three and greater than or equal to zero,
where the sum of a, b, and c is equal to four,
where X is a halogen, and
where R is an alkyl group.

6. The method of claim 1, wherein adding further comprises reacting a halogen substituted disilicon hydride with a nitrogen source.

7. The method of claim 6, wherein the halogen substituted disilicon hydride has the general formula:
Si₂HₐX₆₋ₐ
where a is less than or equal to five and greater than or equal to one, and
where X is a halogen.

8. The method of claim 6, wherein the halogen substituted disilicon hydride has the general formula:
Si₂X₆
where X is a halogen.

9. The method of claim 6, wherein the halogen substituted disilicon hydride has the general formula:
Si₂HₐX_{b}R_{c}
where a is an integer less than or equal to five and greater than or equal to zero,
where b is an integer less than or equal to five and greater than or equal to zero,
where c is an integer less than or equal to five and greater than or equal to zero,
where the sum of a, b, and c is equal to six,
where X is a halogen, and
where R is an alkyl group.

10. The method of claim 2, wherein pre-mixing further comprises adding the halogen substituted silicon hydride and the nitrogen-containing precursor to an organic solvent.

11. The method of claim 10, wherein the silicon source is selected from the group consisting of linear silazanes, branched silazanes, partially substituted aminosilanes with diamene ligands, fully substituted aminosialnes with diamene ligands, silyl cyclopropane, silyl cyclobutane, and halogenated aminosilanes.

12. The method of claim 10, wherein the nitrogen source is selected from the group consisting of dimethyl hydrazine, methyl hydrazine, and asymmetrical dimethyl hydrazine.

13. A method, comprising:
adding a silicon precursor and a nitrogen-containing precursor to a deposition chamber;
exposing the silicon precursor and the nitrogen-containing precursor to electromagnetic waves having a wavelength of about 10 nanometers to about 1 millimeter; and
applying thermal energy to the silicon precursors and the nitrogen-containing precursor.

14. The method of claim 13, further comprising;
setting an operating temperature of the deposition chamber below 550° C.; and
providing a substrate within the deposition chamber, wherein the silicon precursor and the nitrogen-containing precursor form a silicon nitride layer on the substrate.

15. The method of claim 14, wherein exposing further comprises applying ultraviolet light having a wavelength of about 10 nanometers to about 700 nanometers.

16. The method of claim 14, wherein exposing further comprises reacting a silyl-cyclobutane with the nitrogen-containing precursor.

17. The method of claim 14, wherein exposing further comprises reacting a silyl-cyclopropane with the nitrogen-containing precursor.

18. The method of claim 15, wherein adding further comprises passing the silicon precursor and the nitrogen-containing precursor through a distributor coupled to the deposition chamber.

19. The method of claim 15, wherein the silicon precursors and the nitrogen-containing precursors are exposed to ultraviolet light prior to setting the operating temperature of the deposition chamber.

20. The method of claim 18, wherein the silicon precursors and the nitrogen-containing precursors are exposed to ultraviolet light while passing through the distributor and before entering the deposition chamber.

21. An apparatus, comprising:
a deposition chamber having a top and a bottom;
a distributor disposed near the top of the deposition chamber;
a heater coupled to the deposition chamber; and
an electromagnetic wave source coupled to the deposition chamber, the electromagnetic wave source to deliver waves having a wavelength of about 10 nanometers to about 700 nanometers.

22. The apparatus of claim 21, wherein the electromagnetic wave source comprises ultraviolet energy.

23. The apparatus of claim 22, wherein the heater provides an operating temperature of less than 550° C. to deposit a silicon nitride layer on a substrate disposed within the deposition chamber.

24. The apparatus of claim 23, further comprising a second chamber coupled to the deposition chamber, the second chamber to contain a silicon precursor and a nitrogen precursor.

25. The apparatus of claim 21, wherein the heater is disposed around the chamber, and wherein the electromagnetic wave source is integrated within the heater.

26. The apparatus of claim 21, wherein the distributor comprises a showerhead, and wherein the electromagnetic wave source is disposed near the showerhead.

27. The apparatus of claim 21, wherein the electromagnetic wave source is disposed near the bottom of the deposition chamber.
